(19) United States
(12) Patent Application Publication
(10) Pub. No.: US 2026/0074006 A1
(43) Pub. Date: Mar. 12, 2026

(54) ERROR CORRECTION DEVICE, ERROR CORRECTION METHOD, AND SEMICONDUCTOR MEMORY SYSTEM

(71) Applicant: Kioxia Corporation, Tokyo (JP)

(72) Inventors: Takeru SEKIGUCHI, Kamakura Kanagawa (JP); Ryo NOGAMI, Sagamihara Kanagawa (JP); Yuuya NAKANISHI, Kouza Kanagawa (JP); Atsushi TAKAYAMA, Yokohama Kanagawa (JP); Shigeru INADA, Fujisawa Kanagawa (JP); Yousuke KINO, Yokohama Kanagawa (JP); Naoki WADA, Yokohama Kanagawa (JP); Tomohiro NAGATA, Kamakura Kanagawa (JP); Kenji SAKAUE, Yokohama Kanagawa (JP)

(21) Appl. No.: 19/066,448

(22) Filed: Feb. 28, 2025

(30) Foreign Application Priority Data
Sep. 12, 2024 (JP) 2024-158451

(51) Int. Cl. G11C 29/52; G11C 16/10; G11C 16/26

(52) U.S. Cl. CPC G11C 29/52; G11C 16/102; G11C 16/26

(57) ABSTRACT

According to some embodiments, an error correction device includes a decoding circuit configured to read out user data encoded with an error correction code from a nonvolatile memory and perform error correction decoding based on the error correction code on read data of a size, and a rewrite circuit configured to rewrite one or more bits in the read data of the size. The one or more bits include M consecutive bits or a plurality of bits at N-bit intervals. M is a natural number equal to or greater than 1, and N is a natural number equal to or greater than 1.

### CROSS-REFERENCE TO RELATED APPLICATION

This application is based upon and claims the benefit of priority from Japanese Patent Application No. 2024-158451, filed Sep. 12, 2024, the entire contents of which are incorporated herein by reference.

### FIELD

Embodiments described herein relate generally to an error correction device, an error correction method, and a semiconductor memory system for correcting errors in a NAND flash memory.

### BACKGROUND

Data written into a NAND flash memory may contain errors. In order to correct errors in read data, when data is written, an error correction code (hereinafter referred to as ECC) is added to the write data and the data is encoded. Whether the read data contains errors can be determined based on the ECC. Even when the data contains errors, the errors can be corrected up to a certain number as a result of decoding.

Examples of related art include US-A1-2021/0318927, US-A1-2023/0020521, and US-A1-2023/0386598.

### DESCRIPTION OF THE DRAWINGS

FIG. 1 is a block diagram for illustrating an example of an information processing system according to a first embodiment.

FIG. 2 is a block circuit diagram for illustrating an example of an error correction decoding process performed by an ECC circuit, an error information check circuit, and a data rewrite circuit according to the first embodiment.

FIG. 3 is a diagram for illustrating an example of correct data (expected values) assumed for specifying an error pattern according to the first embodiment.

FIG. 4 is a diagram for illustrating an example of read data in which random errors occur, according to the first embodiment.

FIG. 5 is a diagram for illustrating an example of read data in which burst errors occur in addition to the random errors, according to the first embodiment.

FIG. 6 is a flowchart for illustrating an example of an error pattern specifying process according to the first embodiment.

FIG. 7 is a block diagram for illustrating an example of a burst error check circuit according to the first embodiment.

FIG. 8 is a diagram for illustrating an example of the operation of the burst error check circuit according to the first embodiment.

FIG. 9 is a diagram for illustrating an example of the operation of a data rewrite circuit according to the first embodiment.

FIG. 10 is a diagram for illustrating another example of the operation of the data rewrite circuit according to the first embodiment.

FIG. 11 is a diagram for illustrating an example of the operation of a comparison circuit according to the first embodiment.

FIG. 12 is a diagram for illustrating an example of read data according to a second embodiment in which periodic errors occur in addition to random errors.

FIG. 13 is a flowchart for illustrating an example of an error pattern specifying process according to the second embodiment.

FIG. 14 is a block diagram for illustrating an example of a periodic error check circuit according to the second embodiment.

FIG. 15 is a diagram for illustrating an example of the operation of the periodic error check circuit according to the second embodiment.

FIG. 16 is a diagram for illustrating an example of the operation of the periodic error check circuit according to the second embodiment.

FIG. 17 is a diagram for illustrating an example of the operation of the periodic error check circuit according to the second embodiment.

FIG. 18 is a diagram for illustrating an example of the operation of the periodic error check circuit according to the second embodiment.

FIG. 19 is a diagram for illustrating an example of the operation of a data rewrite circuit according to a second embodiment.

FIG. 20 is a diagram for illustrating an example of read data according to a third embodiment in which burst errors and periodic errors occur in addition to random errors.

FIG. 21 is a diagram for illustrating the operation of a data rewrite circuit according to a third embodiment.

FIG. 22 is a diagram for illustrating the operation of the data rewrite circuit according to the third embodiment.

FIG. 23 is a block circuit diagram for illustrating an example of an error correction decoding process performed by an ECC circuit, an error information check circuit, and a data rewrite circuit according to a fourth embodiment.

FIG. 24 is a diagram for illustrating an example of a product code using an XOR code according to the fourth embodiment.

FIG. 25 is a diagram for illustrating an example of error correction using an XOR code according to the fourth embodiment.

FIG. 26 is a diagram for illustrating an example of error correction using an XOR code according to a comparative example.

FIG. 27 is a diagram for illustrating an example of error correction using an XOR code according to the comparative example.

FIG. 28 is a diagram for illustrating an example of error correction using an XOR code according to the fourth embodiment.

FIG. 29 is a flowchart for illustrating an example of an error pattern specifying process according to a sixth embodiment.

### DETAILED DESCRIPTION

Embodiments provide an error correction device, an error correction method, and a semiconductor memory system with improved performance.

In general, according to one embodiment, an error correction device includes a decoding circuit configured to read out user data to which an error correction code is added (e.g., encoded with an error correction code from a nonvolatile memory) from a nonvolatile memory and perform error correction decoding based on the error correction code on read data of a size, and a rewrite circuit configured to rewrite one or more bits in the read data of the size. The one or more bits include M consecutive bits or a plurality of bits at N-bit intervals. M is a natural number equal to or greater than 1, and N is a natural number equal to or greater than 1. Additionally, a semiconductor memory system can be implemented to include a nonvolatile memory and a controller. The controller can be configured to read out user data encoded with an error correction code from the nonvolatile memory. The controller can be configured to perform error correction decoding based on the error correction code on read data of a size. The controller can be configured to rewrite one or more bits in the read data of the size. Additionally, the one or more bits can include M consecutive bits or a plurality of bits at N-bit intervals, the M can be a natural number equal to or greater than 1, and the N can be a natural number equal to or greater than 1.

Hereinafter, embodiments will be described with reference to the drawings. The following description exemplifies devices and methods for embodying the technical ideas of the embodiments, and the technical ideas of the embodiments are not limited to the structures, shapes, arrangements, materials, etc. of elements described below. Modifications that can be easily conceived by those skilled in the art are naturally included within the scope of the disclosure. For clarity of explanation, the size, thickness, planar dimensions, shape, and the like of each element in the drawings may be changed from those of the actual elements and shown diagrammatically. In a plurality of drawings, elements whose dimensional relationships and proportions differ from one another may be included. In a plurality of drawings, corresponding elements may be designated by the same reference numerals and repeated explanations may be omitted. Some elements may be referred to by a plurality of names, but these names are merely illustrative and do not negate the possibility of referring to these elements by other names. Even if an element is not given a plurality of designations, this does not preclude the element from being given another designation. The term “connection” may refer not only to a direct connection, but also to a connection via other elements. Unless it is not specified that the number of elements is plural, the element may be a singular element or a plurality of elements.

### First Embodiment

### (Information Processing System)

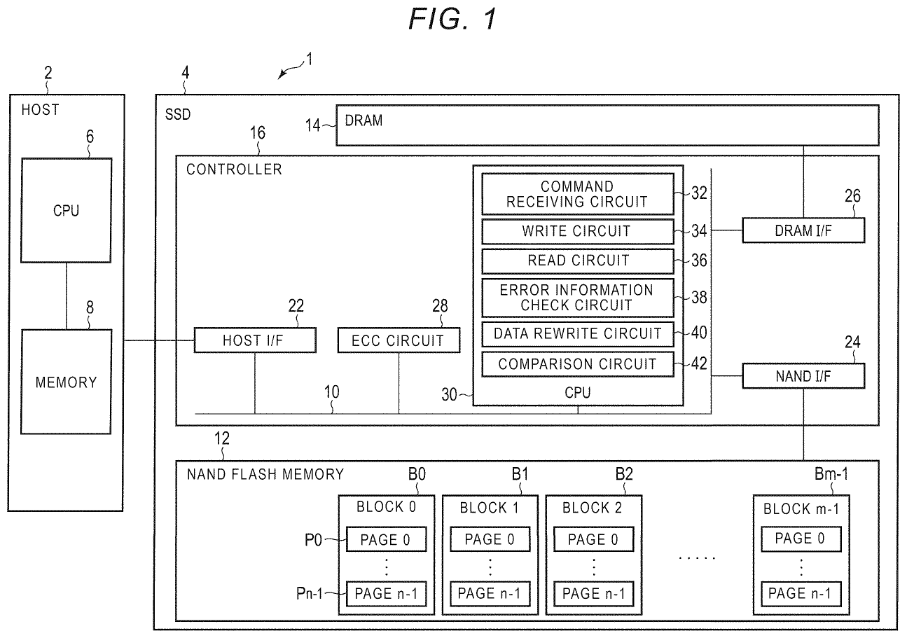

FIG. 1 is a block diagram for illustrating an example of an information processing system according to a first embodiment. The information processing system 1 includes a host device (hereinafter referred to as a host) 2 and a semiconductor memory system 4.

The host 2 may be a storage server that stores a large amount of diverse data in the semiconductor memory system 4, or may be a server or a personal computer.

The host 2 includes a central processing unit (CPU) 6 (also referred to herein as “processor(s),” “processing circuits,” and/or “processing systems”)and a memory 8. The CPU 6 is at least one processor. The CPU 6 controls the operation of the various components of the host 2. The CPU 6 controls the communication between the host 2 and the semiconductor memory system 4. The CPU 6 sends various commands to the semiconductor memory system 4. Examples of commands sent to the semiconductor memory system 4 include a read command and a write command. The host 2 may include a control circuit (interface) that controls communication between the host 2 and the semiconductor memory system 4. The CPU 6 communicates with the semiconductor memory system 4 via the control circuit. Generally, circuits described herein refer to any hardware, software, firmware, or a combination thereof that implements functionality for processing, communication, control, and/or signal manipulation in an electronic system. That is, the term “circuit” may encompass individual electronic components (e.g., logic gates, transistors), integrated circuits (ICs), processing units (e.g., microcontrollers, digital signal processors, application-specific integrated circuits), programmable hardware (e.g., field-programmable gate arrays, system-on-chip devices), software-defined implementations executed by processors, and/or distributed processing architectures implemented across multiple devices or nodes in a system.

The memory 8 is a volatile memory. Examples of volatile memory include dynamic random access memory (DRAM) or static random access memory (SRAM). A storage area of the memory 8 may be allocated as a buffer area in which data is temporarily stored. In the buffer area, data to be written into the semiconductor memory system 4 and data read from the semiconductor memory system 4 may be stored.

The semiconductor memory system 4 is a semiconductor storage device configured to write data to and read data from the nonvolatile memory. An example of the semiconductor memory system 4 is a solid state drive (hereinafter referred to as SSD). Hereinafter, the semiconductor memory system 4 will be referred to as SSD 4. The SSD 4 may be used as a storage for the host 2. The SSD 4 may be built into the host 2, or may be connected to the host 2 via a cable or a network.

The SSD 4 includes a nonvolatile memory 12, a volatile memory 14, and a controller 16.

An example of the nonvolatile memory 12 is a NAND flash memory. Hereinafter, the nonvolatile memory 12 will be referred to as a NAND flash memory 12. Examples of the volatile memory 14 include a DRAM and an SRAM. Hereinafter, the volatile memory 14 will be referred to as a DRAM 14.

The NAND flash memory 12 includes a plurality of blocks B0, B1, B2, . . . , B(m−1). Each of the plurality of blocks B0, B1, B2, . . . , Bm−1 includes a plurality of pages P0, . . . , Pn−1. In this specification, one unspecified block among the plurality of blocks will be referred to as block B. One unspecified page among the plurality of pages is referred to as page P. Block B functions as the minimum unit of a data erase operation. Block B may also be referred to as an erase block or a physical block. Each of the plurality of pages P0, . . . , Pn−1 includes a plurality of memory cells connected to a single word line. Page P functions as a unit for data write operation and data read operation. The word line may function as a unit for data write operation and data read operation.

There is an upper limit to the number of program/erase cycles (P/E cycles) for each block, which is called the maximum P/E cycles. One P/E cycle for a certain block includes a data erase operation for putting all memory cells in the block into an erased state, and a data write operation (program operation) for writing data to each page of the block.

The DRAM 14 may be provided with a storage area for firmware, a cache area for the logical-physical address conversion table, and a buffer area for temporarily storing data.

The firmware is a program for controlling the operation of the controller 16. The firmware may be loaded from the NAND flash memory 12 into the DRAM 14. An example of firmware is a program for implementing error correction encoding and error correction decoding.

The controller 16 functions as a memory controller configured to control the NAND flash memory 12. The controller 16 controls, for example, writing and reading of the NAND flash memory 12. The controller 16 may be implemented by a circuit such as a System on a Chip (SoC). The controller 16 can be configured to perform

The controller 16 may include a host interface (host I/F) 22, a NAND interface (NAND I/F) 24, a DRAM interface (DRAM I/F) 26, an error correction encoding/decoding circuit (hereinafter referred to as an ECC circuit) 28, and a CPU 30. The host I/F 22, the NAND I/F 24, the DRAM I/F 26, the ECC circuit 28 and the CPU 30 may be connected via a bus 10. The controller 16 can be configured to perform operations including reading out user data encoded with an error correction code from the nonvolatile memory. The controller 16 can be configured to perform operations including performing error correction decoding based on the error correction code on read data of a size. The controller 16 can be configured to perform operations including rewriting one or more bits in the read data of the size.

The host I/F 22 functions as a circuit that receives various commands and data from the host 2.

The NAND I/F 24 electrically connects the controller 16 and the NAND flash memory 12. The NAND I/F 24 supports interface standards such as Toggle DDR and Open NAND Flash Interface (ONFI). The NAND I/F 24 functions as a NAND control circuit configured to control the NAND flash memory 12. The NAND I/F 24 may be connected to each of the plurality of memory chips in the NAND flash memory 12 via a plurality of channels. By driving a plurality of memory chips in parallel, the access to the NAND flash memory 12 can be made broadened.

The DRAM I/F 26 functions as a DRAM control circuit configured to control access to the DRAM 14.

The CPU 30 is a processor configured to control the host I/F 22, the NAND I/F 24, the DRAM I/F 26 and the ECC circuit 28. The CPU 30 executes firmware loaded from the NAND flash memory 12 to the DRAM 14 to perform various processes. The firmware is a control program that includes a set of instructions for causing the CPU 30 to execute various processes. The CPU 30 can execute a command process for processing various commands from the host 2. The operation of the CPU 30 is controlled by firmware executed by the CPU 30.

The CPU 30 functions as a command receiving circuit 32, a write circuit 34, a read circuit 36, an error information check circuit 38, a data rewrite circuit 40, and a comparison circuit 42. The CPU 30 may function as each of these circuits 32, 34, 36, 38, and 40 by executing firmware.

Each of the circuits 32, 34, 36, 38, and 40 of the CPU 30 may be implemented by a hardware block.

The command receiving circuit 32 receives a command sent from the host 2. The command receiving circuit 32 controls the ECC circuit 28, the write circuit 34, the read circuit 36, the error information check circuit 38, and the data rewrite circuit 40 based on the received command. When the command receiving circuit 32 receives the read command, it instructs the read circuit 36 to read data from the NAND flash memory 12, and instructs the ECC circuit 28 to perform error correction decoding of the read data. When the command receiving circuit 32 receives a write command, it instructs the ECC circuit 28 to perform error correction encoding on the write data, and instructs the write circuit 34 to write the error correction encoded data to the NAND flash memory 12. The comparison circuit 42 compares the read data with the decoded data to detect a difference. The difference accurately specifies the bit position where the error occurs.

### (Error Correction Code)

An example of an error correction code used by the ECC circuit 28 is a BCH code. In the BCH code, the unit of error occurrence is a bit. The read data from the NAND flash memory 12 is decoded after errors therein are corrected. However, the ECC circuit 28 cannot correct an error, and as a result, a decoding may fail. Possible reasons for the failure of the decoding may be that a defect in the flash memory causes a non-random error pattern that is difficult to correct, or that even if the flash memory is good, stress during use can cause a large number of error bits to occur randomly.

The CPU 30 cannot specify the error pattern when decoding fails. Therefore, the CPU 30 cannot estimate whether the cause of the error is a defect in the flash memory or stress.

The reason why the error pattern cannot be specified when decoding fails is as follows. When the decoding is successful, the ECC circuit 28 (including a decoding circuit within the controller 16 of the semiconductor memory system 4) outputs the decoded data and a decoding success determination result. The decoding circuit can be implemented as part of the ECC circuit 28 within the controller 16 of the semiconductor memory system 4, where it performs error correction decoding on read data using algorithms such as BCH or Reed-Solomon codes. The implementation may be in hardware (e.g., an application-specific integrated circuit (ASIC) or field-programmable gate array (FPGA)), software executed by the controller 16's processor, or a combination of both. It should be understood the decoding circuit operates as a functional component of the ECC circuit 28, interacting with other processing elements in the controller 16 to detect and correct errors in data read from nonvolatile memory. The decoding circuit functionality may be distributed across multiple subsystems in the controller 16, including firmware-driven error correction logic, dedicated hardware accelerators, and/or integrated control mechanisms managing memory access and data integrity. When the decoding fails, the ECC circuit 28 outputs only the decoding failure determination result. When the decoding fails, the data is not decoded, so there is no decoded data and it is not output.

In most cases, the expected value written into the flash memory mounted on an SSD is unknown.

The positions of the error bits in the read data can be identified only by comparing the read data with the decoded data or the expected value and detecting a difference therebetween. However, when decoding fails during the operation of the SSD 4, the decoded data is not output and the expected value is unknown, so that the above comparison cannot be performed and the error bit position cannot be specified. Therefore, the CPU 30 does not know whether the error bits are randomly located, and cannot specify the error pattern.

In the NAND flash memory 12, the following non-random error patterns may occur.
A pattern in which errors occur in a plurality of consecutive bits: a burst error pattern.
A pattern in which errors occur at regular bit intervals: periodic error pattern.

In the following description, the error patterns are the burst error pattern and the periodic error pattern.

The error correction code handled by the ECC circuit 28 according to the embodiment has the following characteristics.
When decoding of a codeword in which error bits have occurred is attempted, whether the decoding will fail or be successful is generally divided based on whether the number of error bits exceeds a certain number of bits. The certain number of bits is called a correction limit.
When a burst error occurs, in which error bits are concentrated in consecutive bit positions, or a periodic error occurs, in which errors are concentrated in bit positions at specific intervals, decoding may not be performed correctly even if the number of error bits is significantly below the correction limit.

The error correction code has a reduced correction capability due to burst errors and periodic errors. Therefore, in the embodiment, burst errors and periodic errors occurring in a codeword are detected, and the cause of error occurrence is specified.

It is assumed that an 8-bit burst information loss error and a 4-bit periodic information loss error may occur in the NAND flash memory 12 according to the embodiment.

As a parameter related to burst errors, a plurality of consecutive bit positions is defined as a section. As a parameter related to periodic errors, a periodic bit position located at a regular bit interval is defined as a sequence. In the embodiment, it is assumed that the expected value is unknown, and therefore details of the error that occurs are unknown at the time when decoding fails.

The CPU 30 according to the embodiment makes some assumptions about the number of bits and then rewrites the read data, makes some assumptions about the burst errors and periodic errors and then rewrites the read data, and decodes the rewritten data. When the decoding fails, the CPU 30 changes the assumption and repeats the flow of changing the rewrite data and performing decoding.

In the following description, the case is described where the assumptions are correct and decoding is successful. Even when repeating the decoding process by changing the assumptions, the decoding may still ultimately fail.

For the sake of simplicity, it is assumed that data before decoding (read data from the NAND flash memory 12) in this embodiment satisfies all of the following conditions.
Including burst errors or periodic errors in addition to random errors.
In a burst error section, information is lost and all bits degenerate to “0”or “1”.
In a periodic error sequence, information is lost and all bits degenerate to “0”or “1”.
If the data remains as is, decoding by the ECC circuit 28 is not successful.
If burst errors or periodic errors are removed, decoding by the ECC circuit 28 is successful.

### (Error Correction/Decoding Process)

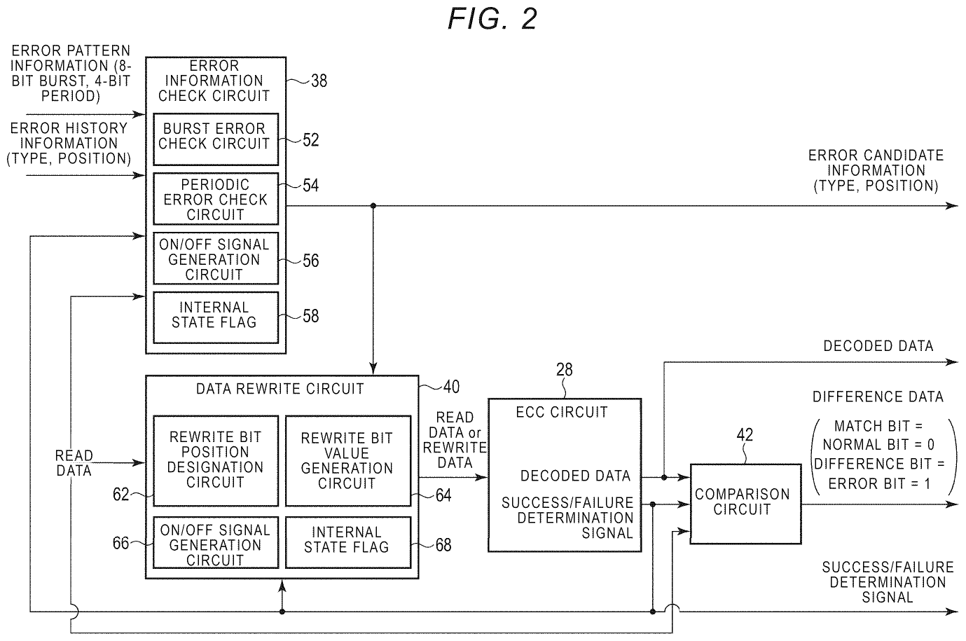

FIG. 2 is a block circuit diagram for illustrating an example of an error correction decoding process performed by the ECC circuit 28, the error information check circuit 38, and the data rewrite circuit 40 according to the first embodiment.

The error pattern information, the error history information, and the read data from the NAND flash memory 12 are input to the error information check circuit 38. The error information check circuit 38 outputs error candidate information.

The error pattern information is information that represents, for example, an 8-bit burst error pattern or a 4-bit periodic error pattern. Before the shipment of the SSD 4, error pattern information on the NAND flash memory 12 that has been checked in advance is written to the NAND flash memory 12. During the operation of the SSD 4, the error pattern information is read from the NAND flash memory 12 and input to the error information check circuit 38. When a new error pattern is detected during the operation of the SSD 4, the error pattern information in the NAND flash memory 12 is updated.

The error history information is error information that has been determined as an error from among the error candidate information detected by the error information check circuit 38. The error history information and the error candidate information are information that indicates the type of error pattern and the position of an error bit. The error candidate information is written into the NAND flash memory 12 at the time of occurrence and is updated. The error history information is written into the NAND flash memory 12 at the determined time and updated.

The error information check circuit 38 includes a burst error check circuit 52, a periodic error check circuit 54, an ON/OFF signal generation circuit 56 and an internal state flag 58. The ON/OFF signal generation circuit 56 generates an ON signal or an OFF signal. The ON signal turns on the internal state flag 58. When the internal state flag 58 is ON, the burst error check circuit 52 and the periodic error check circuit 54 operate. The OFF signal turns off the internal state flag 58. When the internal state flag 58 is OFF, the burst error check circuit 52 and the periodic error check circuit 54 do not operate.

The error candidate information and the read data are input to the data rewrite circuit 40. The data rewrite circuit outputs the read data as is, or outputs rewrite data obtained by rewriting specific bits of the read data.

The data rewrite circuit 40 includes a rewrite bit position designation circuit 62, a rewrite bit value generation circuit 64, an ON/OFF signal generation circuit 66, and an internal state flag 68. The ON/OFF signal generation circuit 66 generates an ON signal or an OFF signal. The ON signal turns on the internal state flag 68. When the internal state flag 68 is ON, the rewrite bit position designation circuit 62 and the rewrite bit value generation circuit 64 operate. The OFF signal turns off the internal state flag 68. When the internal state flag 68 is OFF, the rewrite bit position designation circuit 62 and the rewrite bit value generation circuit 64 do not operate.

The ECC circuit 28 receives the read data or the rewrite data. The ECC circuit 28 performs error correction decoding on the input data. When the decoding is successful, the ECC circuit 28 outputs the decoded data and a success determination signal indicating the decoding success. When the decoding fails, the ECC circuit 28 does not output the decoded data, but outputs a failure determination signal indicating the decoding failure. The decoded data is written into the NAND flash memory 12. The success/failure determination signal is input to the error information check circuit 38, the data rewrite circuit 40 and the comparison circuit 42.

The comparison circuit 42 receives the read data, the decoded data, and the success/failure determination signal. When receiving a determination signal indicating successful decoding, the comparison circuit 42 compares the read data with the decoded data, and outputs difference data indicating a difference in bit values at each bit position. In the difference data, bits where both input data match are normal bits, and the bit value is “0”. In the difference data, the difference bit where both input data do not match is an error bit, and the bit value is “1”. Furthermore, the bit value of a normal bit may be “1” and the bit value of an error bit may be “0”.

### (Specification of Error Pattern)

The read data read from the NAND flash memory 12 is stored in a buffer in the DRAM 14. Data is not read from the NAND flash memory 12 each time the error information check circuit 38 performs a process. Data is not read from the NAND flash memory 12 each time the data rewrite circuit 40 performs a process.

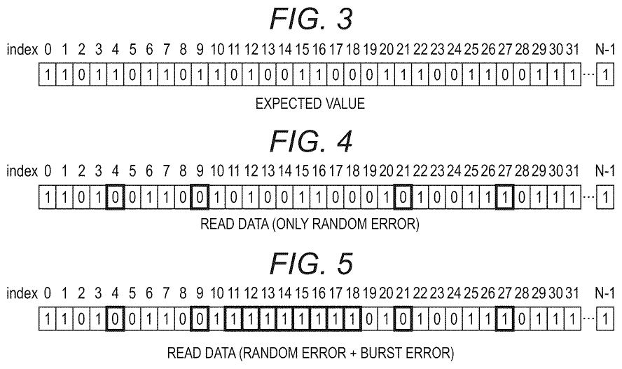

FIG. 3 is a diagram for illustrating an example of correct data (hereinafter, referred to as an expected value) assumed for specifying an error pattern according to the first embodiment. The data length (one frame) handled in the error correction encoding/decoding is assumed to be N-bit data, and the bit positions from the beginning to the end in one frame are called an index. The indexes are 0, 1, 2, . . . , N−1, starting from the beginning.

When the ECC circuit 28 fails to decode, the error information check circuit 38 checks the read data and narrows down bit positions where burst errors or periodic errors are suspected. The data rewrite circuit 40 rewrites the bit values at the narrowed-down bit positions. The ECC circuit 28 attempts to decode the rewrite data again. When decoding that has been attempted fails again, the bit values are rewritten to different values and the decoding is repeated. As a result, when decoding is successful, it is found that the suspected error occurs. By comparing the data before and after decoding, the precise position of the error bit can be specified.

In the first embodiment, it is assumed that 8-bit burst errors occur in addition to random errors in the read data (data before decoding) from the NAND flash memory 12.

FIG. 4 is a diagram for illustrating an example of read data in which random errors occur, according to the first embodiment. It is assumed that the data (bold frames) at random indexes=4, 9, 21, and 27 are incorrect. Read data containing only random errors can be decoded by the ECC circuit 28.

FIG. 5 is a diagram for illustrating an example of read data in which burst errors occur in addition to random errors, according to the first embodiment. In the read data, in addition to the random errors (index=4, 9, 21, 27) shown in FIG. 4, a burst error occurs in which the bit values (bold frame) of a section of eight consecutive bits of indexϵ[11, 18] degenerate to “1” due to information loss. Read data including a burst error cannot be decoded by the ECC circuit 28 as it is. The burst error also includes a burst error in which a bit value degenerates to “0” due to information loss.

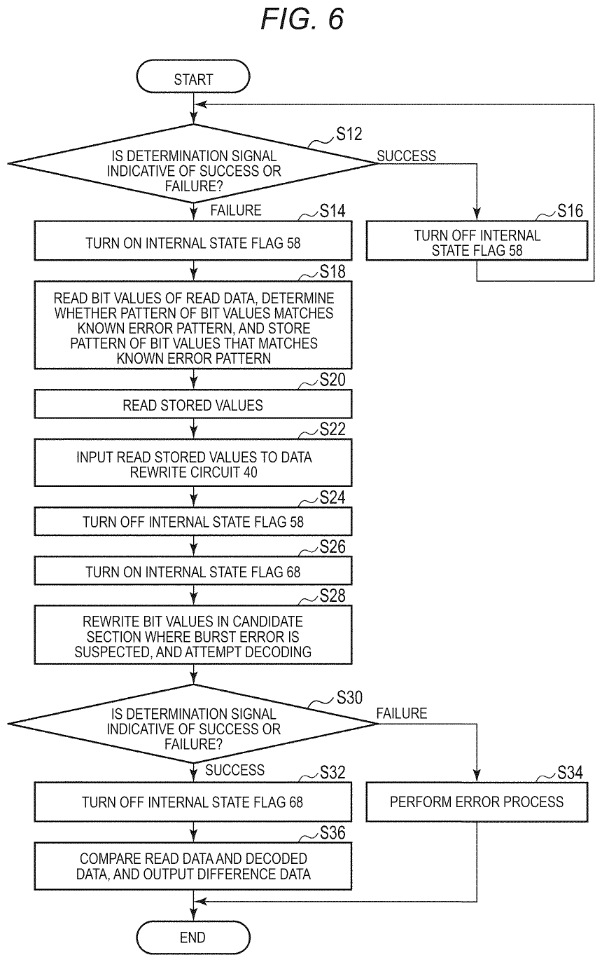

FIG. 6 is a flowchart for illustrating an example of an error pattern specifying process performed by the error information check circuit 38 according to the first embodiment.

The error information check circuit 38 determines whether the determination signal output by the ECC circuit 28 indicates a success or failure (step S12). When the determination signal indicates failure, the ON/OFF signal generation circuit 56 generates an ON signal and turns on the internal state flag 58 (step S14). When the determination signal indicates success, the ON/OFF signal generation circuit 56 generates an OFF signal and turns off the internal state flag 58 (step S16). When the internal state flag 58 is OFF, the burst error check circuit 52 and the periodic error check circuit 54 do not operate. After step S16 is executed, step S12 is executed again.

When the internal state flag 58 is ON (step S14), the burst error check circuit 52 and the periodic error check circuit 54 operate. It is assumed that an 8-bit burst error pattern and a 4-bit periodic error pattern are provided to the error information check circuit 38 as known error patterns of the NAND flash memory 12. The burst error check circuit 52 and periodic error check circuit 54 read out the bit values of the read data, determine whether the pattern of bit values matches a known periodic error pattern, and store the pattern of bit values that matches the known error pattern (step S18).

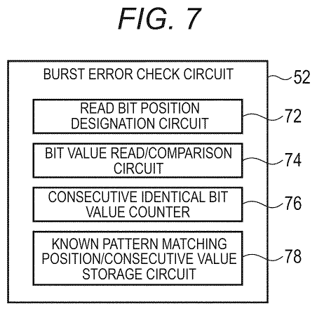

FIG. 7 is a block diagram for illustrating an example of the burst error check circuit 52 according to the first embodiment. The burst error check circuit 52 includes a read bit position designation circuit 72, a bit value read/comparison circuit 74, a consecutive identical bit value counter 76, and a known pattern matching position/consecutive value storage circuit 78. The initial value of the consecutive identical bit value counter 76 is set to 0.

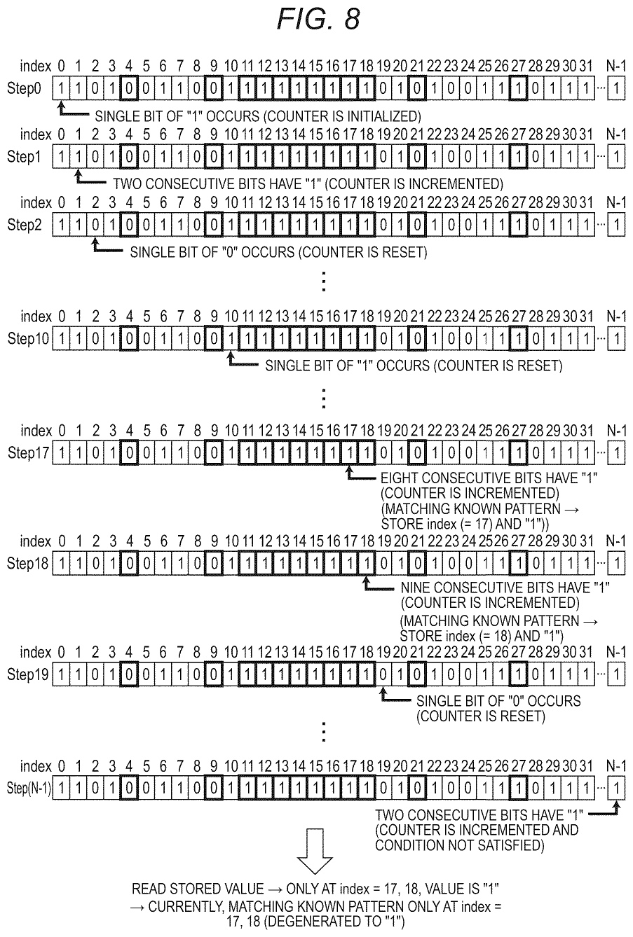

FIG. 8 is a diagram for illustrating an example of the operation of the burst error check circuit 52 according to the first embodiment. The read bit position designation circuit 72 designates an index in sequence starting from 0. The bit value read/comparison circuit 74 reads out the bit value of each index in order starting from 0, and compares the bit value of each index with the bit value of the immediately preceding index. When the bit value of each index is different from the bit value of the immediately preceding index, that is, when a single bit of bit value “1” or “0” occurs, the consecutive identical bit value counter 76 is reset (initialized) (Step 0 in FIG. 8).

When the bit value of each index is the same as the bit value of the immediately preceding index, the value of the consecutive identical bit value counter 76 is incremented by 1 (Step 1 in FIG. 8). When the value of the consecutive identical bit value counter 76 is n, this means that (n+1) consecutive bits have the bit value “1”or “0”.

When the bit value of each index is different from the bit value of the immediately preceding index, that is, when a single bit of bit value “1” or “0” occurs, the consecutive identical bit value counter 76 is reset (initialized) (Step 2 in FIG. 8).

When eight consecutive bits have the same bit value, the value of the consecutive identical bit value counter 76 becomes 7 (Step 17 in FIG. 8). When the value of the consecutive identical bit value counter 76 becomes 7, a specified burst error pattern (8-bit burst error pattern) is detected.

The known pattern matching position/consecutive value storage circuit 78 stores the currently read index (=17) and bit value (=“1”). From the values stored in the storage circuit 78 and the known 8-bit burst error pattern, it is found that 8 consecutive bits have the bit value “1”at indexϵ[10, 17].

The bit value of the next index (=18) is read out (Step 18 in FIG. 8). Since the bit value is “1”, the value of the consecutive identical bit value counter 76 becomes “8”. At this time, since the state in which the same bit value occurs in eight consecutive bits continues, the pattern of bit values matches a known error pattern. Therefore, the known pattern matching position/consecutive value storage circuit 78 stores the currently read index (=18) and bit value (=“1”).

The bit value of the next index (=19) is read out (Step 19 in FIG. 8). Since the bit value is “0”, the consecutive identical bit value counter 76 is reset (initialized).

Similarly, bit values are read out up to index (N−1) (Step(N−1) in FIG. 8).

Returning to the explanation of FIG. 6, when the check up to Step(N−1) in FIG. 8 is completed, the burst error check circuit 52 reads out the stored values (index: 17, bit value “1” and index: 18, bit value “1”) from the storage circuit 78 (step S20 in FIG. 6).

In the first embodiment, it is assumed that a pattern of bit values matching a known burst error pattern is found only at indexϵ[10, 17] and indexϵ[11, 18] of the read data. Therefore, burst errors are suspected to occur at indexϵ[10, 17] and indexϵ[11, 18]. The indexϵ[10, 17] and indexϵ[11, 18] are candidates for the sections in which burst errors occur.

Like the burst error check circuit 52, the periodic error check circuit 54 also reads out the bit values of the read data, determines whether the pattern of bit values matches a known periodic error pattern, and stores the pattern of bit values that matches the known error pattern. In the first embodiment, it is assumed that no pattern suspected of being a periodic error is detected. The details of the check by the periodic error check circuit 54 will be explained in the second embodiment.

The error information check circuit 38 inputs the stored value read from the storage circuit 78 to the data rewrite circuit 40 (step S22 in FIG. 6). The ON/OFF signal generation circuit 56 generates an OFF signal and turns off the internal state flag 58 (step S24). Thus, the burst error check circuit 52 and the periodic error check circuit 54 do not operate.

In the data rewrite circuit 40, the ON/OFF signal generation circuit 66 generates an ON signal to turn on the internal state flag 68 (step S26). When the internal state flag 68 is ON, the rewrite bit position designation circuit 62 and the rewrite bit value generation circuit 64 operate.

The rewrite bit position designation circuit 62 and the rewrite bit value generation circuit 64 rewrite the bit values in each of the two candidate sections where an 8-bit burst error is suspected, and the ECC circuit 28 attempts to decode the rewrite data (step S28).

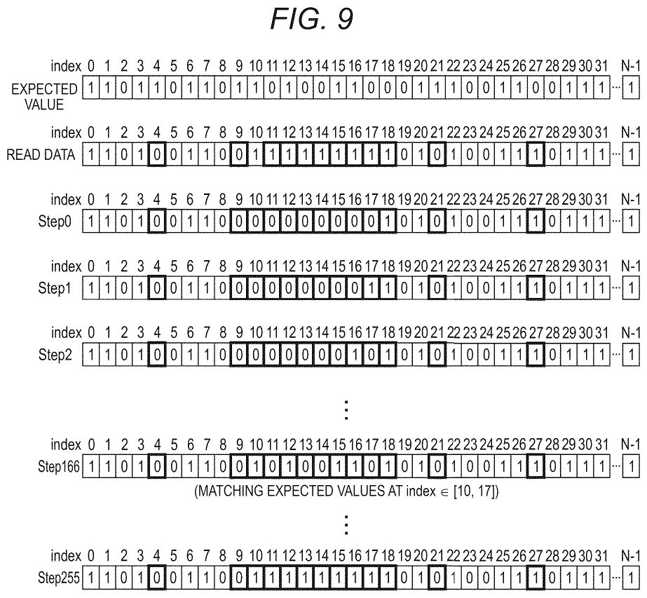

FIG. 9 is a diagram for illustrating an example of the operation of the data rewrite circuit 40 according to the first embodiment. The rewrite bit position designation circuit 62 first designates a section of indexϵ[10, 17] among two candidate sections where 8-bit burst errors in read data are suspected to occur. The rewrite bit value generation circuit 64 sequentially rewrites the bit values of the 8 bits in the designated section of the read data in 2⁸=256 different ways (Step 0 to Step 255 in FIG. 9). The read data is assumed to include a random error and a burst error.

The ECC circuit 28 attempts to decode the rewrite data, and supplies a success/failure determination signal to the data rewrite circuit 40. It is assumed that decoding of all pieces of rewritten data of 256 types for bit values in the section of indexϵ[10, 17] fails.

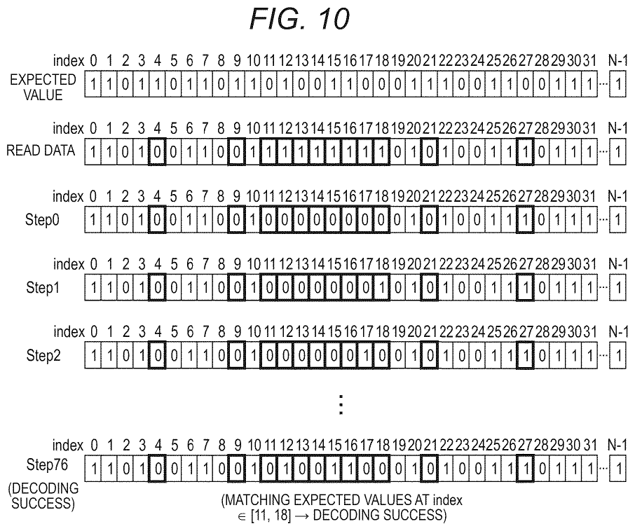

FIG. 10 is a diagram for illustrating another example of the operation of the data rewrite circuit 40 according to the first embodiment. The rewrite bit position designation circuit 62 designates the next indexϵ[11, 18] as a rewrite candidate section. The rewrite bit value generation circuit 64 sequentially rewrites the bit values of the 8 bits in the designated section of the read data in 2⁸=256 different ways (Step 0 to Step 76 in FIG. 10). The read data is assumed to include a random error and a burst error. In Step 76 of FIG. 10, the rewritten data at indexϵ[11, 18] matches the expected values, and therefore the decoding is successful. The ECC circuit 28 feeds back a success determination signal to the data rewrite circuit 40. The one or more bits can include the M consecutive bits (e.g., a contiguous sequence of bits within a detected burst error section) and the plurality of bits at the N-bit intervals (e.g., bits located at fixed intervals corresponding to a detected periodic error pattern). The one or more bits can include the M consecutive bits with leading bits (e.g., the first bit in each modified M-bit sequence) spaced apart (e.g., positioned at regular N-bit intervals to align with a periodic error pattern) at N-bit intervals.

Returning to the explanation of FIG. 6, the data rewrite circuit 40 determines whether the determination signal output by the ECC circuit 28 indicates success or failure (step S30). When the determination signal indicates success, the ON/OFF signal generation circuit 66 generates an OFF signal and turns off the internal state flag 68 (step S32). When the internal state flag 68 is OFF, the rewrite bit position designation circuit 62 and the rewrite bit value generation circuit 64 do not operate.

When the determination signal indicates failure, the data rewrite circuit 40 executes an error process (step S34). Examples of the error process include writing the determination signal to the NAND flash memory 12 and transmitting the determination signal to a server or the like (not shown).

When decoding is successful, it is found that a burst error occurs. Depending on the correction capability of the ECC circuit 28, there is a possibility that decoding may be successful even in Step 166 in FIG. 9, where the burst error section and the inversion section do not exactly match. In this way, the burst error period may not be specified accurately.

In order to accurately specify the burst error section, the comparison circuit 42 compares the read data of the NAND flash memory 12 with the decoded data output from the ECC circuit 28, and outputs the difference data (step S36).

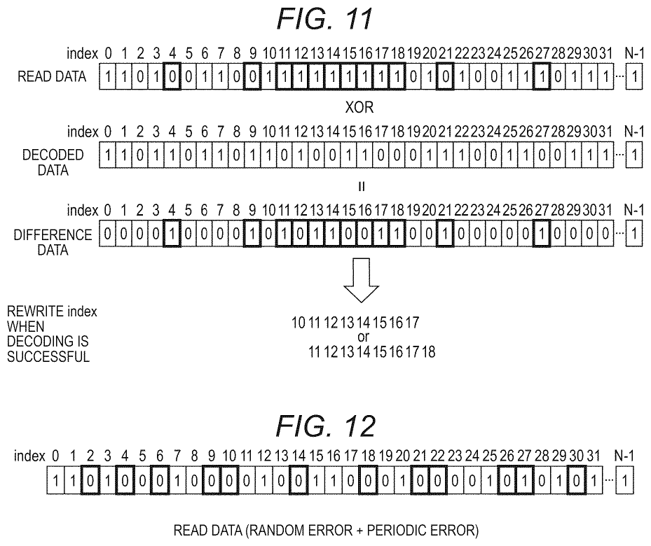

FIG. 11 is a diagram for illustrating an example of the operation of the comparison circuit 42 according to the first embodiment. The comparison circuit 42 generates difference data by performing an exclusive OR (XOR) operation on the bit values at the bit position having the same index (e.g., corresponding bit positions in the read data and the decoded data). The difference data is N-bit data, and is “0” in bit positions where the values before and after decoding match, and is “1” in bit positions where they do not match.

The CPU 30 can specify the more precise position of the burst error section by checking the vicinity of the rewritten bit position when decoding is successful, out of the difference data. The bit values of nine consecutive bits at indexϵ[10, 18] are “1”, but the bit value at index=10 is not erroneous, and the bit values at index=11 and 18 are erroneous. Therefore, the burst error section can be specified as indexϵ[11, 18]. The CPU 30 can determine one of the plurality of pieces (also referred to herein as “error pattern instances” and/or “entries”)(e.g., individual sets of error candidate data, each representing a suspected error pattern including its type, bit position, and/or occurrence frequency) of error candidate information as the error history information based on the difference data.

According to the first embodiment, it is possible to rewrite some bit values of read data based on burst error pattern information that may occur in the NAND flash memory 12, and to attempt decoding again. This makes it possible to specify the burst error position in the NAND flash memory 12.

### Second Embodiment

The circuit configuration of the information processing system according to the second embodiment is the same as that shown in FIG. 1, and the circuit configurations of the ECC circuit 28, the error information check circuit 38 and the data rewrite circuit 40 according to the second embodiment are the same as those shown in FIG. 2, and is therefore omitted from the illustration.

### (Specification of Error Pattern)

FIG. 12 is a diagram for illustrating an example of read data in which periodic error occurs in addition to random errors, according to the second embodiment. In the read data, in addition to the random errors (index=4, 9, 21, 27) shown in FIG. 4, a periodic error occurs in which a 4-bit periodic sequence of indexϵ[4k+2] (k is an integer) degenerates to “0” due to information loss. Read data including a periodic error cannot be decoded by the ECC circuit 28 as it is. The periodic error also includes a periodic error in which a bit value degenerates to “0” due to information loss.

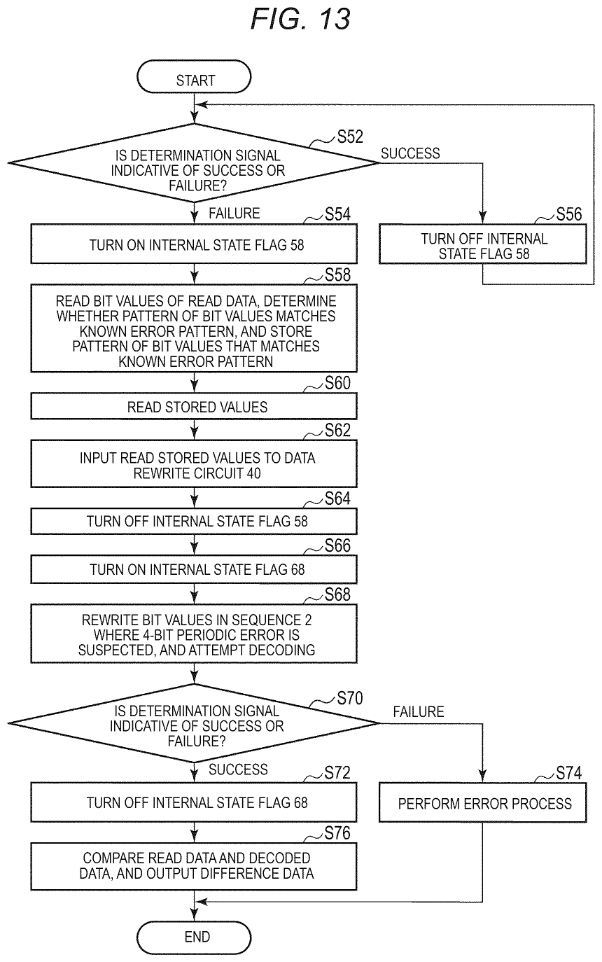

FIG. 13 is a flowchart for illustrating an example of an error pattern specifying process performed by the error information check circuit 38 according to the second embodiment.

The error information check circuit 38 determines whether the determination signal output by the ECC circuit 28 indicates a success or failure (step S52). When the determination signal indicates failure, the ON/OFF signal generation circuit 56 generates an ON signal and turns on the internal state flag 58 (step S54). When the determination signal indicates success, the ON/OFF signal generation circuit 56 generates an OFF signal and turns off the internal state flag 58 (step S56). When the internal state flag 58 is OFF, the burst error check circuit 52 and the periodic error check circuit 54 do not operate. After step S56 is executed, step S52 is executed again.

When the internal state flag 58 is ON, the burst error check circuit 52 and the periodic error check circuit 54 operate. An 8-bit burst error pattern and a 4-bit periodic error pattern are provided to the error information check circuit 38 as known error patterns of the NAND flash memory 12. The burst error check circuit 52 and periodic error check circuit 54 read out the bit values of the read data, determine whether the pattern of bit values matches a known periodic error pattern, and store the pattern of bit values that matches the known error pattern (step S58). In the second embodiment, it is assumed that as the check result by the burst error check circuit 52, the pattern of read data suspected to have a burst error is not detected.

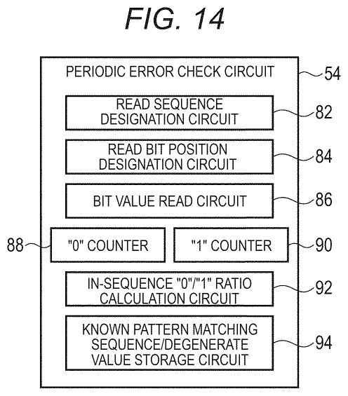

FIG. 14 is a block diagram for illustrating an example of the periodic error check circuit 54 according to the second embodiment. The periodic error check circuit 54 includes a read sequence designation circuit 82, a read bit position designation circuit 84, a bit value read circuit 86, a “0” counter 88, a “1” counter 90, an in-sequence bit value ratio calculation circuit 92, and a known pattern matching sequence/degenerate value storage circuit 94.

The periodic error check circuit 54 counts the cumulative number of bit values “0” and “1” in each sequence, and calculates the ratio of “0”/“1” in the sequence. The NAND flash memory 12 is designed such that the ratio of bit values “0” and “1” is almost equal throughout, and data is written such that there is no bias between bit values “0” and “1”. Therefore, if no periodic error occurs, the ratio of bit values “0” to bit values “1” in the sequence is approximately 1:1. When the ratio of “0”/“1” in a sequence significantly deviates from 1:1, the occurrence of a periodic error is suspected. Criteria for determining whether the ratio has deviated significantly from 1:1 are preset.

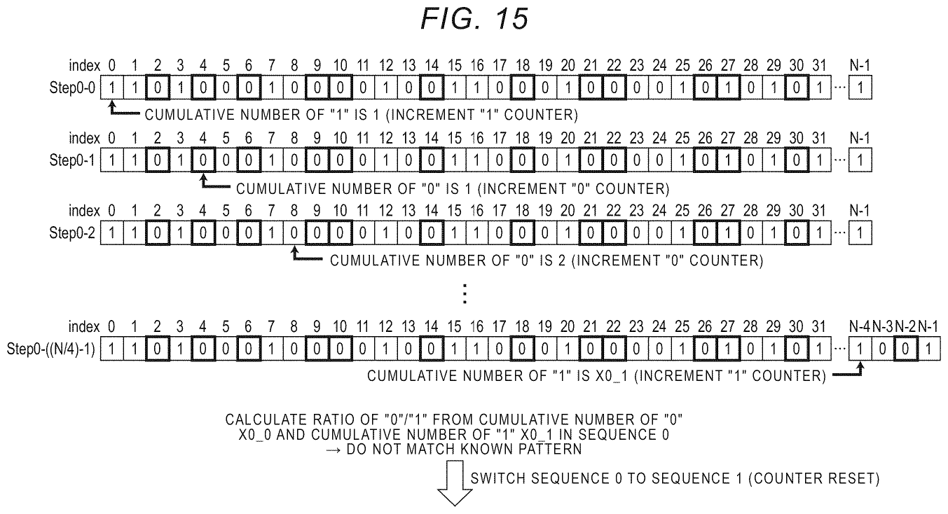

FIGS. 15, 16, 17, and 18 are diagrams for illustrating an example of the operation of the periodic error check circuit 54 according to the second embodiment.

The read sequence designation circuit 82 first sequentially reads out the bit values of the 4-bit periodic sequence starting from index=0 of the read data (called sequence 0) (Step 0-0 to Step 0−(N/4) in FIG. 15). The “0” counter 88 counts the total number of read bit values “0”. The “1” counter 90 counts the total number of read bit values “1”.

When the checking of sequence 0 is completed in Step 0 to Step 0−(N/4) in FIG. 15, the ratio of “0”/“1” is calculated from the cumulative number of bit values “0” X0_0 and the cumulative number of bit values “1” X0_1 in sequence 0. In sequence 0, there is no bias in the ratio of “0”/“1”, and the pattern of bit values of sequence 0 is determined not to match the known pattern.

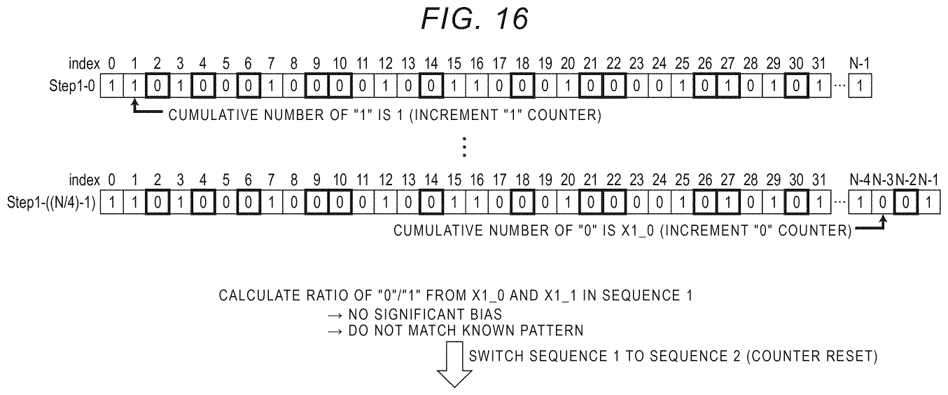

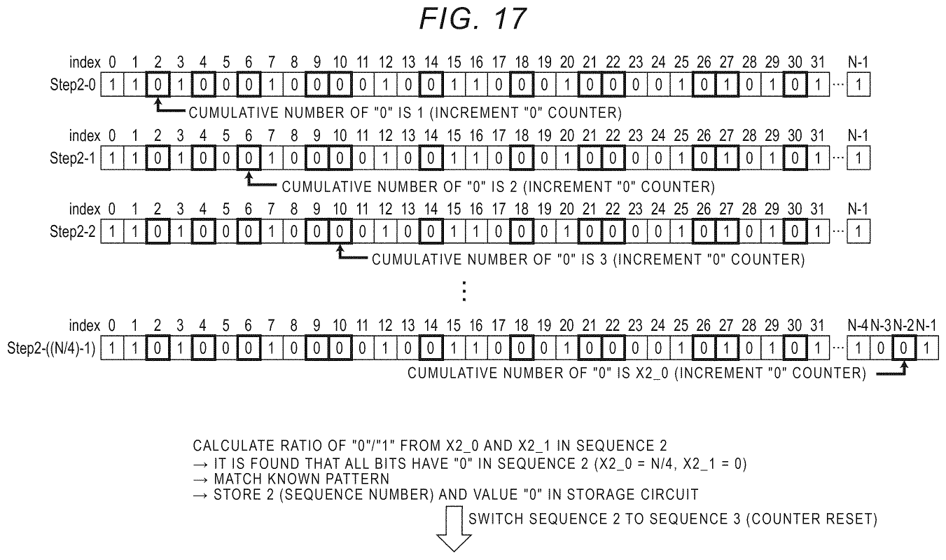

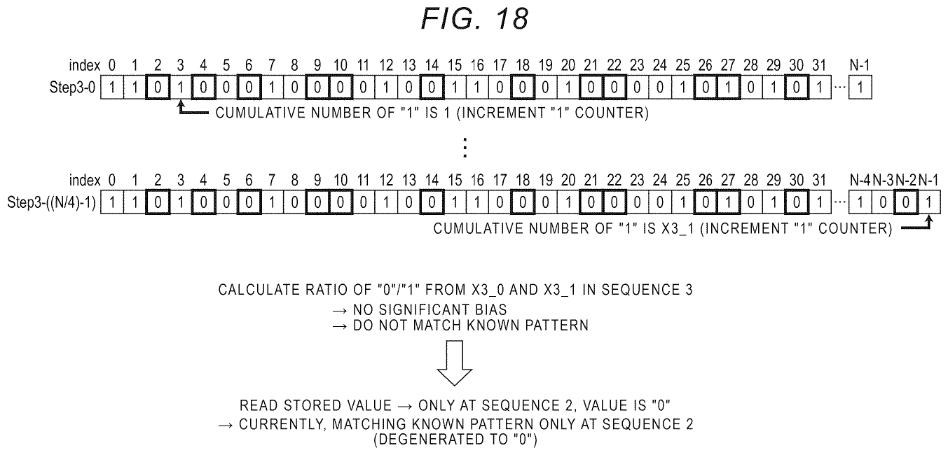

After the checking of sequence 0 is completed, the 4-bit periodic sequence starting from index=1 (called sequence 1) is checked in a similar manner (FIG. 16). This checking is repeated for the entire sequence (FIGS. 17 and 18). The number of sequences to be checked is equal to the period of the sequence. In the second embodiment, the number of sequence to be checked is four: sequence 0 to sequence 3.

In the sequences 0, 1, and 3, it is assumed that the pattern of bit values does not match the known pattern. On the other hand, in sequence 2 (Step 2-0 to Step 2−(N/4) in FIG. 17), it is found that all bits degenerate to “0”, and it is determined that the pattern of bit values matches the known pattern. Therefore, the known pattern matching sequence/degenerate value storage circuit 94 stores the sequence number: 2 and the degenerate value: “0”.

Returning to the explanation of FIG. 13, when checking of all the sequences is completed, the periodic error check circuit 54 reads out the stored value (sequence number: 2, degenerate value: “0”) from the storage circuit 94 (step S60 in FIG. 13). In the second embodiment, it is assumed that a pattern of bit values matching a known periodic error pattern is only seen in sequence 2 of the read data. From this, it is suspected that a periodic error occurs in sequence 2. Sequence 2 is a candidate for a sequence in which a periodic error occurs.

The error information check circuit 38 inputs the value read from the storage circuit 94 to the data rewrite circuit 40 (step S62 in FIG. 13). The ON/OFF signal generation circuit 56 generates an OFF signal and turns off the internal state flag 58 (step S64). Thus, the burst error check circuit 52 and the periodic error check circuit 54 do not operate.

In the data rewrite circuit 40, the ON/OFF signal generation circuit 66 generates an ON signal to turn on the internal state flag 68 (step S66). When the internal state flag 68 is ON, the rewrite bit position designation circuit 62 and the rewrite bit value generation circuit 64 operate.

The data rewrite circuit 40 rewrites the bit values in sequence 2 where a 4-bit periodic error is suspected, and the ECC circuit 28 attempts decoding (step S68).

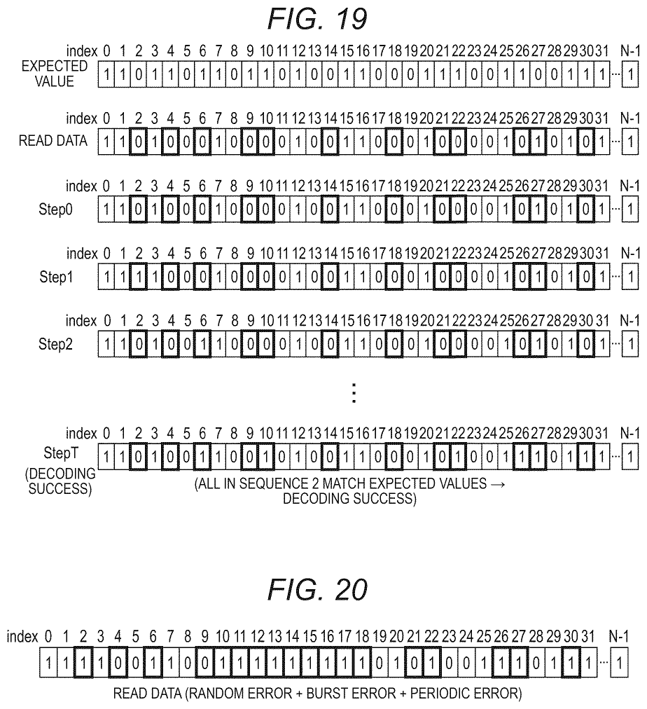

FIG. 19 is a diagram for illustrating an example of the operation of the data rewrite circuit 40 according to the second embodiment. The rewrite bit position designation circuit 62 designates the bit positions in sequence 2 where the occurrence of a 4-bit periodic error in the read data is suspected. The rewrite bit value generation circuit 64 sequentially rewrites the bit values of the sequence of read data in 2^{(N/4)} different ways (Step 0 to Step T in FIG. 19). The read data is assumed to include a random error and a periodic error.

The ECC circuit 28 attempts to decode the rewrite data, and supplies a success/failure determination signal to the data rewrite circuit 40. Although there is a possibility that decoding will be successful in the middle of rewriting in 2^{(N/4)} ways, in this embodiment, decoding is considered to be successful first when all the bit values of sequence 2 are rewritten so as to match the expected values (Step T in FIG. 19).

Returning to the explanation of FIG. 13, the data rewrite circuit 40 determines whether the determination signal output by the ECC circuit 28 indicates success or failure (step S70). When the determination signal indicates success, the ON/OFF signal generation circuit 66 generates an OFF signal and turns off the internal state flag 68 (step S72). When the internal state flag 68 is OFF, the rewrite bit position designation circuit 62 and the rewrite bit value generation circuit 64 do not operate.

When the determination signal indicates failure, the data rewrite circuit 40 executes an error process (step S74). An example of the error process is the same as the process in step S74.

When decoding is successful, it is found that a periodic error occurs. As in the first embodiment, even in the second embodiment, decoding can be successful even when the entire sequence 2 does not exactly match the expected values. Even in the second embodiment, the period of the periodic error may not be accurately specified.

In order to accurately specify the period of the periodic error, the comparison circuit 42 compares the read data of the NAND flash memory 12 with the decoded data output from the ECC circuit 28, and outputs the difference data (step S76). By checking sequence 2 of the difference data, the occurrence of a periodic error in sequence 2 is specified reliably.

Furthermore, unlike the burst error, in the periodic error, bit positions do not overlap between sequences, so that it is almost certain that the periodic error sequence is sequence 2 when decoding is successful.

According to the second embodiment, it is possible to rewrite some bit values of read data based on periodic error pattern information that may occur in the NAND flash memory 12, and to attempt decoding again. This makes it possible to specify the period of the periodic error in the NAND flash memory 12.

### Third Embodiment

The circuit configuration of the information processing system according to the third embodiment is the same as that shown in FIG. 1, and the circuit configurations of the ECC circuit 28, the error information check circuit 38 and the data rewrite circuit 40 according to the third embodiment are the same as those shown in FIG. 2, and is therefore omitted from the illustration.

### (Specification of Error Pattern)

FIG. 20 is a diagram for illustrating an example of read data in which burst errors and periodic errors occur in addition to random errors, according to the third embodiment. In the read data, in addition to the random errors (index=4, 9, 21, 27) shown in FIG. 4, a burst error (e.g., a sequence of errors affecting multiple consecutive bit positions within a localized region of the data) occurs in which the bit values of a section of eight consecutive bits at indexϵ[11, 18] degenerate to “1” due to information loss, and a periodic error occurs in which the bit values of a 4-bit periodic sequence at indexϵ[4k+2] (k is an integer) degenerate to “1” due to information loss. Read data including a burst error and a periodic error cannot be decoded by the ECC circuit 28 as it is. The burst error also includes an error in which a bit value degenerates to “0” due to information loss. The periodic error also includes an error in which a bit value degenerates to “0”due to information loss.

As in the first and second embodiments, when the ECC circuit 28 outputs a failure determination signal, the burst error check circuit 52 and periodic error check circuit 54 start operating to determine whether a known error pattern occurs in the read data. The process of checking the burst error pattern is the same as that shown in FIG. 6. The process of checking the periodic error pattern is the same as that shown in FIG. 13. As a result, it is assumed that burst errors are suspected to occur in two sections of indexϵ[10, 17] and indexϵ[11, 18] of the read data, and periodic errors are suspected to occur in sequence 2. The storage circuit 78 of the burst error check circuit 52 stores values relating to candidates for burst error section. The storage circuit 94 of the periodic error check circuit 54 stores values relating to candidates for periodic errors.

When the error information check circuit 38 transmits the stored values in the storage circuit 78 of the burst error check circuit 52 and the stored values in the storage circuit 94 of the periodic error check circuit 54 to the data rewrite circuit 40, the burst error check circuit 52 and the periodic error check circuit 54 stop operating, and the rewrite bit position designation circuit 62 and the rewrite bit value generation circuit 64 operate.

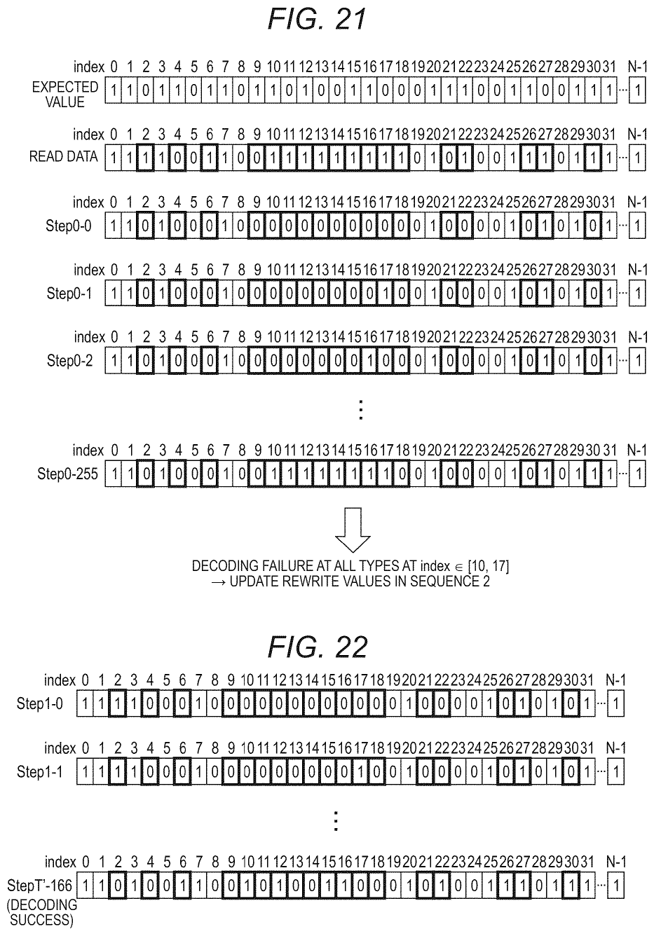

FIGS. 21 and 22 are diagrams for illustrating the operation of the data rewrite circuit 40 according to the third embodiment.

In order to specify a burst error, the rewrite bit position designation circuit 62 and the rewrite bit value generation circuit 64 rewrite the bit values in the section of indexϵ[10, 17] in a certain sequence of read data. The rewrite bit position designation circuit 62 and the rewrite bit value generation circuit 64 first determine the first rewrite values in sequence 2 where the 4-bit periodic errors are suspected to occur, and then sequentially rewrite the bit values of indexϵ[10, 17] of the read data in 2⁸=256 ways (Step 0-0 to Step 0-255 in FIG. 21). For a bit value that belongs to both the rewrite section and the rewrite sequence, the rewrite section takes precedence (for example, index=10 in FIG. 21).

The ECC circuit 28 attempts to decode the rewrite data, and supplies a success/failure determination signal to the data rewrite circuit 40. In the third embodiment, it is assumed that decoding of all pieces of the rewrite data in 256 ways in sequence 2 has failed.

When decoding of all pieces of rewrite data of indexϵ[10, 17] of sequence 2 fails, the rewrite bit position designation circuit 62 and the rewrite bit value generation circuit 64 update the rewrite values of sequence 2 and rewrite indexϵ[10, 17] again (Step 1-0, . . . in FIG. 22).

In the third embodiment, an update cycle for an 8-bit burst section is nested within an update cycle for a 4-bit periodic sequence.

Since there are overlapping bits in the burst error section and the periodic error sequence, the burst errors and periodic errors are removed in any of the combinations of sequence 2 and indexϵ[10, 17], resulting in successful decoding (Step T′-166 in FIG. 22).

When decoding is successful, it is found that burst errors and periodic errors have occurred. As in the first and second embodiments, in order to accurately specify an error pattern, the comparison circuit 42 creates difference data before and after decoding. The CPU 30 can specify the more precise positions of the burst error section and the periodic error sequence by checking the vicinity of the rewritten bit position when decoding is successful, out of this difference data.

Furthermore, as for the simultaneous occurrence of burst errors and periodic errors, in addition to the case where the errors occur completely separately as in the third embodiment, there may also be a case where burst errors occur periodically. For example, when an 8-bit burst error and a 32-bit periodic error are given as known error patterns, the 8-bit burst error may occur in a 32-bit period, such as indexϵ[0, 7], indexϵ[32, 39], indexϵ[64, 7] . . . . In this case as well, both the burst error check circuit 52 and the periodic error check circuit 54 suspect the occurrence of an error. When two types of errors occur independently, it is considered that burst errors have occurred in a plurality of sections. When burst errors occur periodically, it is considered that periodic errors have occurred in a plurality of sequences. However, in both cases, the error bit positions ultimately indicate the same bit position group, so the procedure for rewriting depends on the circuit configuration and settings.

According to the third embodiment, it is possible to rewrite some bit values of read data based on burst error pattern information and periodic error pattern information that may occur in the NAND flash memory 12, and to attempt decoding again. This makes it possible to specify the position of the burst error and the period of the periodic error in the NAND flash memory 12.

### Fourth Embodiment

In a fourth embodiment, when decoding is successful, it is determined whether the decoding is erroneous decoding.

In the first to third embodiments, when decoding fails, many bit values are rewritten and then decoding is attempted again. Therefore, there is a risk that data is decoded to a value different from the expected value. Since the ECC circuit 28 determines whether the decoding has failed or is successful regardless of whether the decoded data matches or does not match the expected value, it is not possible to check whether the decoding is correct based on a single code alone. When it is desired to check whether the decoding is correct, the ECC circuit 28 needs to use a product code such as an XOR code.

Since the circuit configuration of the information processing system according to the fourth embodiment is the same as that in FIG. 1, it is not shown.

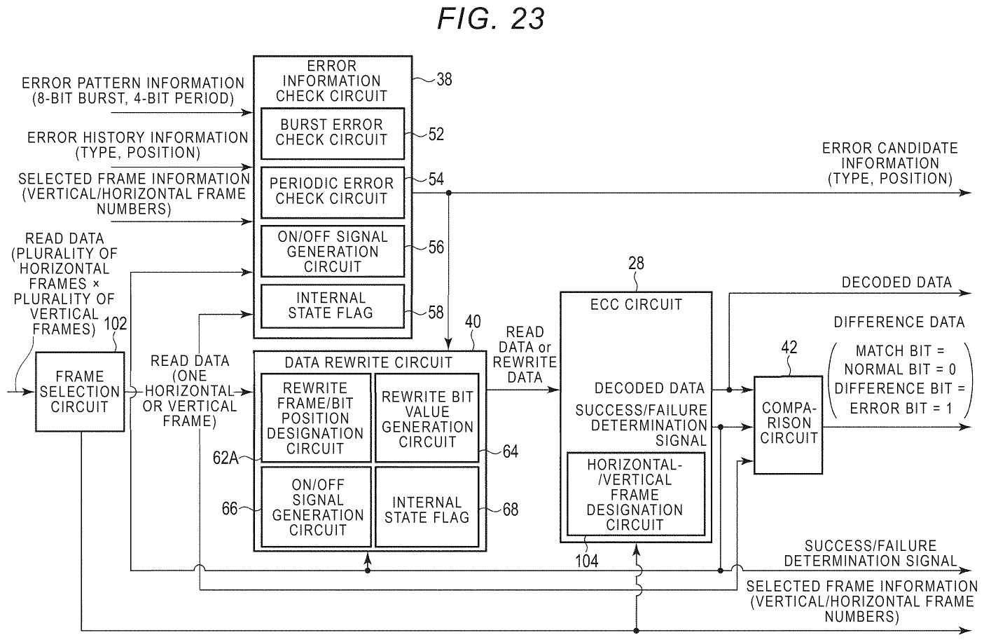

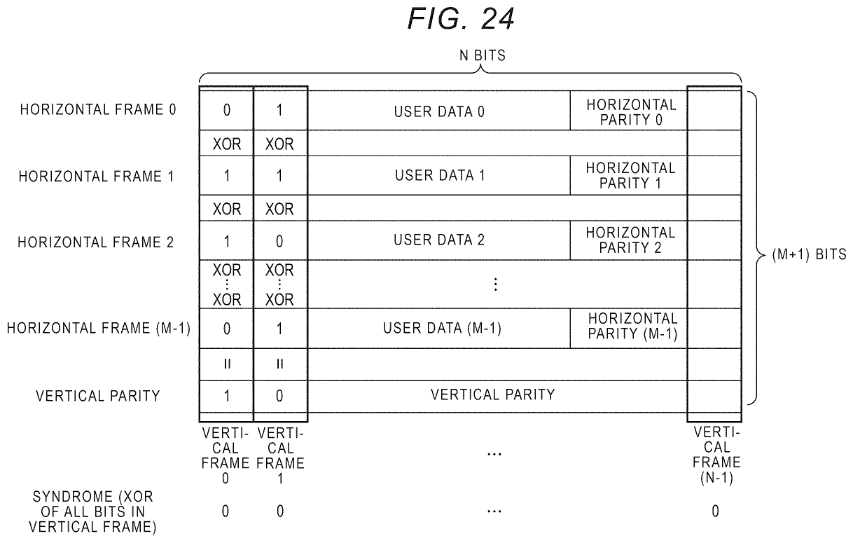

FIG. 23 is a block circuit diagram for illustrating an example of an error correction decoding process performed by the ECC circuit 28, the error information check circuit 38, and the data rewrite circuit 40 according to the fourth embodiment. FIG. 24 is a diagram for illustrating an example of a product code using an XOR code according to the fourth embodiment.

The data handled in the first to third embodiments corresponds to the horizontal frame in FIG. 24. The horizontal frame includes a bit value corresponding to the user data and a bit value corresponding to the parity (for convenience, referred to as horizontal parity in FIG. 24) added during encoding (e.g., encoded with an error correction code) by the ECC circuit 28. When writing M horizontal frames to the NAND flash memory 12, the ECC circuit 28 performs an XOR operation on the same bit positions of the M horizontal frames and generates the result as XOR parity (for convenience, referred to as vertical parity in FIG. 24). The (M+1) bits obtained by combining the M bits subjected to the XOR operation and one vertical parity bit are called a vertical frame of the XOR code.

When an XOR operation is performed on all bit values in a vertical frame, if there is no bit error in the vertical frame or if there is an error in the even number of bits, the result of the XOR operation is “0”. When there is an error in the vertical frame, the result of the XOR operation is “1”. The result of this XOR operation is called the syndrome of the XOR code. When the error in the vertical frame is almost one bit or less, the XOR code is very effective for checking whether decoding is correct.

The read data that is read from the NAND flash memory 12 is configured with a plurality of horizontal frames×a plurality of vertical frames. The read data is input to a frame selection circuit 102 (FIG. 23). The frame selection circuit 102 selects and outputs one of a plurality of horizontal frames and a plurality of vertical frames. The error information check circuit 38 also receives selected frame information (vertical/horizontal frame numbers). The ECC circuit 28 includes a horizontal/vertical frame designation circuit 104. The horizontal/vertical frame designation circuit 104 designates a vertical frame or a horizontal frame based on the selected frame information. The data rewrite circuit 40 according to the fourth embodiment includes a rewrite frame/bit position designation circuit 62A instead of the rewrite bit position designation circuit 62 according to the first embodiment.

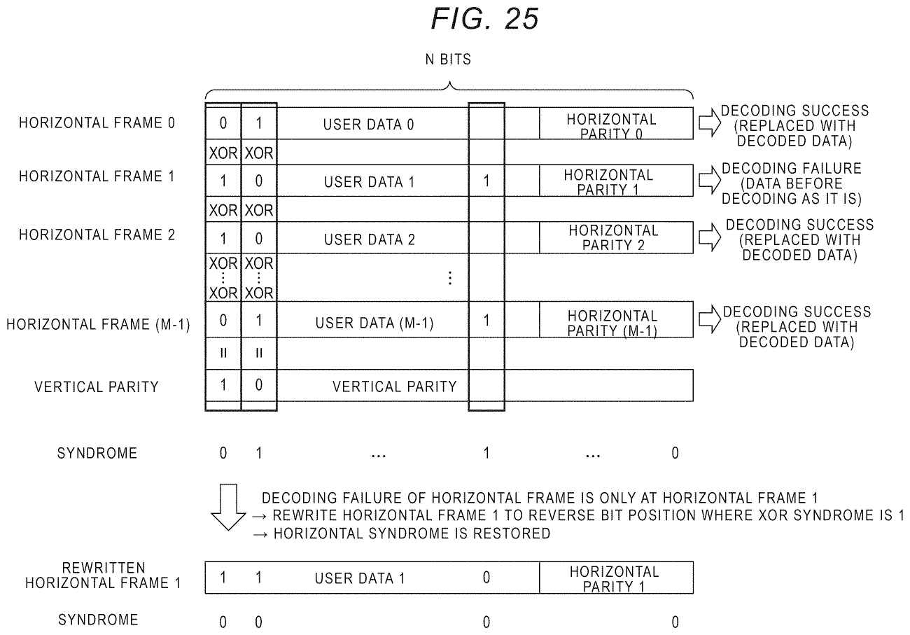

FIG. 25 is a diagram for illustrating an example of error correction using the XOR code according to the fourth embodiment. The XOR code is used for rescue when decoding of each horizontal frame fails. It is assumed that the ECC circuit 28 attempts to decode horizontal frame 1 and fails. The ECC circuit 28 reads out M horizontal frames configuring the XOR code, and attempts to decode each of the horizontal frames. As a result, it is assumed that all frames except for horizontal frame 1 are decoded without using the first to third embodiments. Since the decoding is successful without any rewriting, the risk of erroneous decoding is negligible. In this case, the bit position where the syndrome of the XOR code is “1” necessarily means that the bit value of horizontal frame 1 is erroneous. Therefore, if the bit value at the corresponding bit position in horizontal frame 1 is rewritten so as to be inverted, horizontal frame 1 is correctly restored.

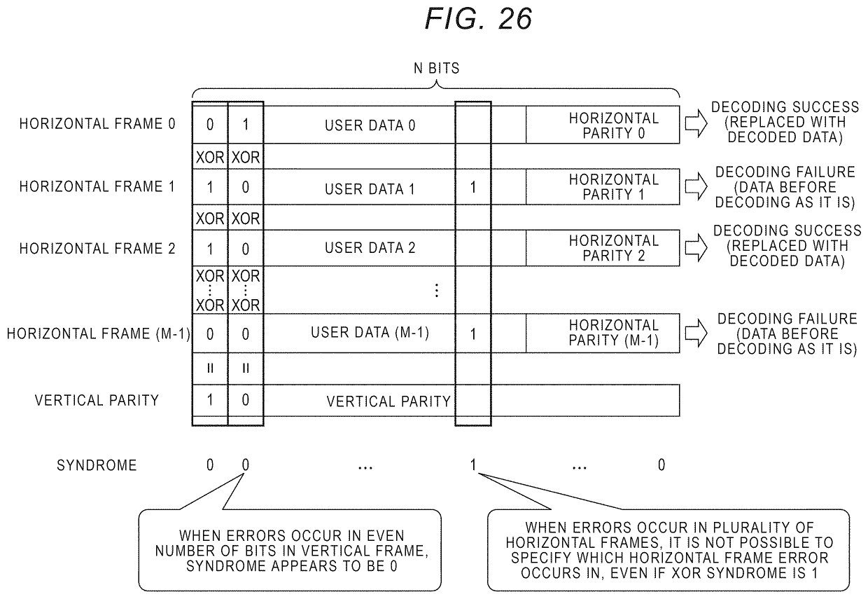

FIG. 26 is a diagram for illustrating an example of error correction using an XOR code according to a comparative example. When decoding fails in a plurality of horizontal frames, there may be an error in the even number of bits in a vertical frame. In this case, the XOR syndrome appears to be “0”. Further, even when the bit positions where the XOR syndrome becomes “1” are identified, it is not possible to specify which horizontal frame the error occurs in. In this case, no further decoding attempts can be made.

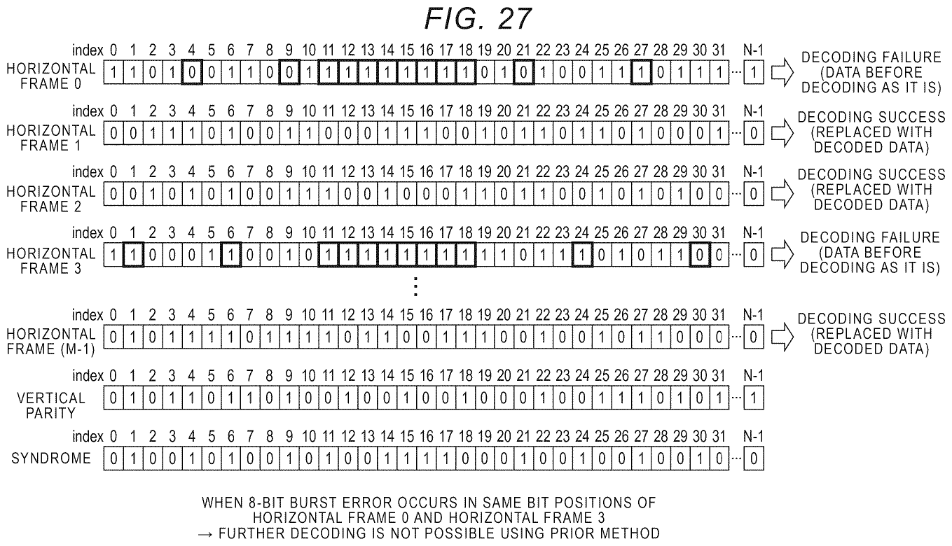

FIG. 27 is a diagram for illustrating an example of error correction using an XOR code according to the comparative example of FIG. 26. Due to the structure of the NAND flash memory 12, burst errors and periodic errors caused by the same fault in the NAND flash memory 12 may occur at the same bit positions in the plurality of horizontal frames. In light of this, in the fourth embodiment, it is assumed that burst errors occur in the section of indexϵ[11, 18] of two horizontal frames (horizontal frame 0 and horizontal frame 3). In this case, in the comparative example shown in FIG. 26, further decoding is not possible. When the process of the first embodiment is performed on horizontal frame 0, there is a possibility that decoding will be successful, but there is a risk of erroneous decoding due to the rewriting involved.

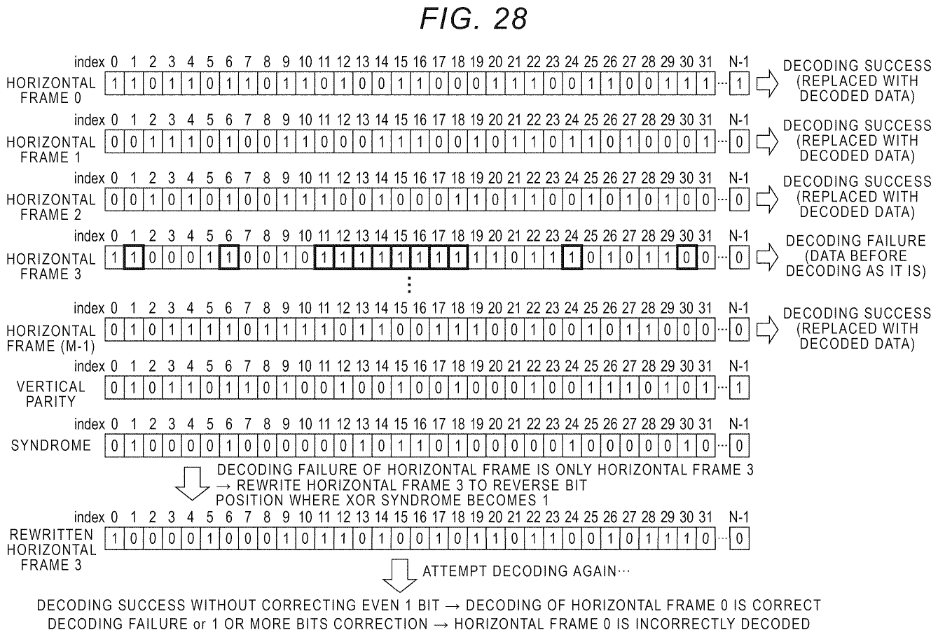

Therefore, when horizontal frame 0 is decoded by executing the processing of the first embodiment, it is possible to check whether this decoding is correct by performing the error correction shown in FIG. 25, as shown in FIG. 28.

FIG. 28 is a diagram for illustrating an example of error correction using the XOR code according to the fourth embodiment. The data rewrite circuit 40 rewrites the horizontal frame 3 in accordance with the error correction shown in FIG. 25. When decoding of the rewritten horizontal frame 3 is attempted again, depending on the result, the following can be said.
When the decoding is successful without a single bit being corrected, all bits in the horizontal frame are successfully corrected and the XOR syndrome of all vertical frames is also “0”, which means that the decoding of horizontal frame 0 is correct.
When the decoding fails or even one bit is corrected, the XOR syndrome is “1”, which means that the decoding of horizontal frame 0 is incorrect.

According to the fourth embodiment, it is possible to determine whether the decoding of a horizontal frame is correct or incorrect, and it is recognized that rewriting increases the risk of erroneous decoding.

### Fifth Embodiment

In the fifth embodiment, as in the first to fourth embodiments, the CPU 30 writes the type and bit position of an error when decoding is successful as error history information into the NAND flash memory 12 and makes it non-volatile.

When the error information check circuit 38 checks for errors from the next time onwards, the CPU 30 can read out the non-volatile error history information from the NAND flash memory 12 and supply the error history information to the error information check circuit 38.

The error information check circuit 38 according to the first to fourth embodiments checks for burst errors and periodic errors in order from the bit position of index=0, resulting in poor check efficiency. However, the error information check circuit 38 according to the fifth embodiment can, by referring to error history information, give priority to checking errors of the same type or bit position as errors that have occurred in the past, thereby improving check efficiency and shortening check time.

### Sixth Embodiment

The sixth embodiment relates to the operation of an ON/OFF signal generation circuit 56 that determines whether to operate the burst error check circuit 52 and the periodic error check circuit 54. In the first to fifth embodiments, the ON/OFF signal generation circuit 56 generates an ON signal when the determination signal output from the ECC circuit 28 indicates a failure.

The ON/OFF signal generation circuit 56 according to the sixth embodiment determines whether to generate an ON signal or an OFF signal depending on the cause of the decoding failure. The causes of the decoding failure include the occurrence of random errors with a number of bits exceeding the correction limit (hereinafter referred to as cause A) and the occurrence of burst errors or periodic errors (hereinafter referred to as cause B). In the case of a decoding failure due to cause B, the ON/OFF signal generation circuit 56 according to the sixth embodiment generates an ON signal to operate the burst error check circuit 52 and the periodic error check circuit 54. In the case of a decoding failure due to cause A, the ON/OFF signal generation circuit 56 according to the sixth embodiment does not generate an ON signal but generates an OFF signal, thereby preventing the burst error check circuit 52 and the periodic error check circuit 54 from operating. In the sixth embodiment, the number of opportunities for the burst error check circuit 52 and the periodic error check circuit 54 to operate is reduced compared to the first to fifth embodiments. Thus, it is possible to improve the efficiency of the operation of the error information check circuit 38.

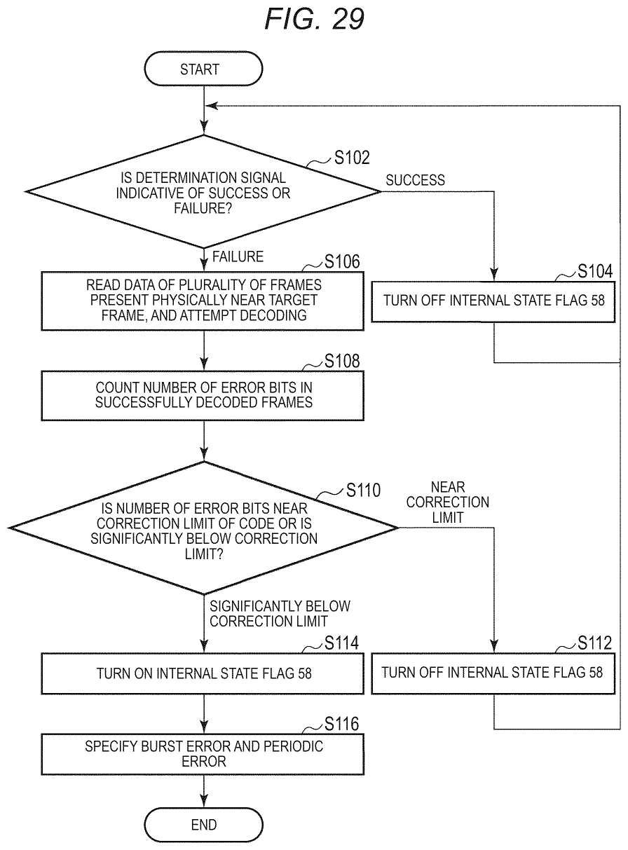

FIG. 29 is a diagram for illustrating an example of the operation of the error information check circuit 38 according to the sixth embodiment. The ECC circuit 28 performs error correction decoding on the read signal of a certain frame (called a target frame), and outputs a determination signal indicative of the success or failure of the decoding. The error information check circuit 38 determines whether the determination signal output by the ECC circuit 28 indicates a success or failure (step S102). When the determination signal indicates success, the ON/OFF signal generation circuit 56 generates an OFF signal and turns off the internal state flag 58 (step S104). When the internal state flag 58 is OFF, the burst error check circuit 52 and the periodic error check circuit 54 do not operate. After step S104 is executed, step S102 is executed again.

When the determination signal indicates failure, the burst error check circuit 52 and the periodic error check circuit 54 read data of a plurality of frames stored physically near the memory position of the target frame in the NAND flash memory 12, and attempt decoding using the ECC circuit 28 (step S106). This is because it is considered that the positions of frames stored in the NAND flash memory 12 are close to each other and have similar stress conditions, and therefore the states of frames adjacent to the target frame are checked.

The burst error check circuit 52 and periodic error check circuit 54 count the number of error bits in the successfully decoded frames (step S108). When a plurality of frames are successfully decoded, the burst error check circuit 52 and the periodic error check circuit 54 count the number of error bits in each of the plurality of successfully decoded frames, and obtain the average value of the number of error bits of the plurality of frames.

The burst error check circuit 52 and the periodic error check circuit 54 determine whether the number of error bits or the average value thereof is near the correction limit of the code or is significantly below the correction limit (step S110). Since strong stress is applied to the NAND flash memory 12 in the vicinity of the target frame, from the fact that the number of error bits or its average value is near the correction limit of the code, it is considered that the cause of the decoding failure of the target frame is the cause A.

When the number of error bits or the average value thereof is near the code correction limit, the ON/OFF signal generation circuit 56 generates an OFF signal to turn off the internal state flag 58 (step S112). When the internal state flag 58 is OFF, the burst error check circuit 52 and the periodic error check circuit 54 do not operate. After step S112 is executed, step S102 is executed again.

When the number of error bits or its average value is significantly below the correction limit of the code, it is unlikely that strong stress such as cause A is being applied only to the target frame, and it is considered that the cause of the decoding failure of the target frame is the cause B. Therefore, in this case, the ON/OFF signal generation circuit 56 generates an ON signal and turns on the internal state flag 58 (step S114). When the internal state flag 58 is ON, the burst error check circuit 52 and the periodic error check circuit 54 operate.

The burst error check circuit 52 and the periodic error check circuit 54 rewrite bit values relating to the burst section and sequence in the read data to determine whether decoding is successful, and specify burst errors and periodic errors (step S116).

According to the sixth embodiment, the burst error check circuit 52 and the periodic error check circuit 54 operate in response to the cause of the decoding failure, so that the checking operation is performed efficiently.

### Seventh Embodiment

As in the sixth embodiment, the seventh embodiment also relates to the operation of an ON/OFF signal generation circuit 56 that determines whether to operate the burst error check circuit 52 and the periodic error check circuit 54. The seventh embodiment differs from the sixth embodiment in that the ECC circuit 28 of the seventh embodiment uses a product code, whereas the ECC circuit 28 of the sixth embodiment handles data corresponding to horizontal frames in the product code, as in the first to third embodiments.

In the seventh embodiment, each horizontal frame described in the fourth embodiment is encoded by a product code regardless of the vertical frame. The product code of the seventh embodiment is configured as follows. The ECC circuit 28 first determines an inner code (corresponding to the XOR code in the vertical frame of the fourth embodiment) that configures the product code. Next, the ECC circuit 28 arranges the user data in a matrix, encodes each row and each column with an inner code, and places a parity to the user data. This results in each bit of user data being doubly encoded in both row and column directions.

The ECC circuit 28 decodes this product code by repeating row-wise decoding and column-wise decoding. When the syndrome of the inner codes of all rows and all columns becomes “0”, the decoding of the product code is completed. When there remains a row or column whose syndrome is not “0” even after repeating row-wise or column-wise decoding a predetermined number of times, the decoding of the product code is determined to have failed.

When attempting to decode a product code, the total number of rows and columns whose syndromes are not “0” are known for each decoding iteration. For example, it is assumed that 64-bit user data is arranged in 8 rows and 8 columns, and a total of 16 inner codes are created, 8 in the row direction and 8 in the column direction. In the first decoding, it is assumed that non-zero syndromes occur in a total of seven inner codes in four rows and three columns. In the next decoding, it is assumed that non-zero syndromes occur in a total of three inner codes in two rows and one column. Then, in the next decoding, it is assumed that the syndromes become “0” in all rows and all columns, and the product code is successfully decoded. In this case, the number of non-zero syndromes occurring among the 16 inner codes in 8 rows and 8 columns transitions to 7, 3, and 0 with each iteration of decoding. In the seventh embodiment, attention is focused on this transition.

When errors of the number of bits exceeding the correction limit occur (cause A), it is considered that the number of non-zero syndromes is larger compared to the successfully decoded frames and does not converge to 0 within a predetermined number of times. On the other hand, when a burst error or periodic error occurs (cause B), the number of error bits itself is relatively small, so it is considered that the number of non-zero syndromes is not significantly different from that of successfully decoded frames but does not converge to 0 within a predetermined number of times due to slow decrease.

The error information check circuit 38 checks the transition of the number of non-zero syndromes in frames where the product code has been successfully decoded and the transition when decoding has failed, before the SSD 4 is shipped, and writes the check results in the NAND flash memory 12. Next, when decoding of the target frame (read data from the NAND flash memory 12) has failed during the operation of the SSD 4, the error information check circuit 38 checks the transition of the number of non-zero syndromes in the target frame. When the number of non-zero syndromes changes significantly from the initial timing and overlaps with transition examples of other decoding failure frames, the cause of the decoding failure of the target frame is considered to be cause A. In this case, the ON/OFF signal generation circuit 56 generates an OFF signal and turns off the internal state flag 58. When the internal state flag 58 is OFF, the burst error check circuit 52 and the periodic error check circuit 54 do not operate.

On the other hand, when the number of non-zero syndromes is not significantly different from that of successfully decoded frames, the cause of the decoding failure of the target frame is considered to be cause B. In this case, the ON/OFF signal generation circuit 56 generates an ON signal and turns on the internal state flag 58. When the internal state flag 58 is ON, the burst error check circuit 52 and the periodic error check circuit 54 operate.

According to the seventh embodiment, even in the error correction process using the product code, the burst error check circuit 52 and the periodic error check circuit 54 operate according to the cause of the decoding failure, so that the check operation is performed efficiently.

### (Modification)

It is assumed that the ECC circuit 28 according to each of the above embodiments performs encoding/decoding based on the BCH code or the like in which the unit of error occurrence is a bit. However, the ECC circuit 28 may perform encoding/decoding based on a Reed-Solomon code or the like, in which a symbol consisting of a plurality of bits is used as the unit of error occurrence.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An error correction device, comprising:
a decoding circuit configured to read out user data encoded with an error correction code from a nonvolatile memory and perform error correction decoding based on the error correction code on read data of a size; and
a rewrite circuit configured to rewrite one or more bits in the read data of the size;
wherein the one or more bits comprise M consecutive bits or a plurality of bits at N-bit intervals, and wherein M is a natural number equal to or greater than 1, and wherein N is a natural number equal to or greater than 1.

2. The error correction device of claim 1, wherein the one or more bits comprise the M consecutive bits and the plurality of bits at the N-bit intervals.

3. The error correction device of claim 1, wherein the one or more bits comprise M consecutive bits with leading bits spaced apart at N-bit intervals.

4. The error correction device of claim 1, further comprising:
a comparison circuit configured to compare the read data of the size with an output signal of the decoding circuit, and detect a pattern of a bit when the read data and the output signal do not match.

5. The error correction device of claim 1, wherein:
the decoding circuit is configured to:
perform the error correction decoding on each of a plurality of pieces of the read data of the size;
calculate an exclusive OR of the plurality of pieces of read data of the size at same bit positions to generate exclusive OR data of the size; and
calculates an exclusive OR of the plurality of pieces of read data and the exclusive OR data at same bit positions to generate syndrome data of the size; and
the rewrite circuit is configured to determine the one or more bits in accordance with the syndrome data.

6. The error correction device of claim 1, wherein the error correction code comprises a BCH code or a Reed-Solomon code.

7. The error correction device of claim 1, further comprising:
a detection circuit configured to detect an error pattern of the read data of the size by comparing the read data of the size with a predetermined bit error pattern data;
wherein the rewrite circuit rewrites the one or more bits based on the error pattern.

8. The error correction device of claim 7, wherein:
the decoding circuit outputs a determination signal, when the error correction decoding has failed;
the detection circuit operates upon receiving the determination signal; and
the decoding circuit performs the error correction decoding on the rewritten read data of the size.

9. The error correction device of claim 7, wherein:
the detection circuit detects a bit in which a loss error occurs in the read data of the size; and
the rewrite circuit determines the one or more bits depending on a bit in which a loss error occurs.

10. The error correction device of claim 7, wherein:
the decoding circuit outputs a determination signal, when the error correction decoding has failed; and
the detection circuit operates upon receiving the determination signal.

11. The error correction device of claim 7, further comprising:
a write circuit that writes information representing the error pattern detected by the detection circuit into the nonvolatile memory.

12. The error correction device of claim 11, wherein the information representing the error pattern comprises information representing that a plurality of error bits are consecutive or a plurality of error bits occur periodically.

13. The error correction device of claim 11, wherein the information representing the error pattern comprises information representing a rewrite bit when the decoding circuit executes the error correction decoding on the rewritten read data of the size and the decoding is successful.

14. The error correction device of claim 11, wherein the information representing the error pattern comprises information representing an error pattern different from the predetermined bit error pattern data.

15. The error correction device of claim 7, further comprising:
a determination circuit that, when the decoding circuit fails in the error correction decoding, determines whether a cause of the failure is a random error or a cause of the failure is a burst error or a periodic error, and outputs a first signal indicating that the cause of the failure is the random error or a second signal indicating that the cause of the failure is the burst error or the periodic error;
wherein the detection circuit does not operate when the first signal is received, and operates when the second signal is received.

16. The error correction device of claim 15, wherein:
the decoding circuit counts the number of error bits in the read data of the size that are successfully decoded; and
the determination circuit outputs the first signal when the number of error bits is near a correction limit of the decoding circuit, and outputs the second signal when the number of error bits falls below the correction limit.

17. The error correction device of claim 15, wherein the decoding circuit performs the error correction decoding based on a product code.

18. A semiconductor memory system, comprising:
a nonvolatile memory; and
a controller configured to:
read out user data encoded with an error correction code from the nonvolatile memory;
perform error correction decoding based on the error correction code on read data of a size; and
rewrite one or more bits in the read data of the size;
wherein the one or more bits comprise M consecutive bits or a plurality of bits at N-bit intervals, and wherein M is a natural number equal to or greater than 1, and wherein N is a natural number equal to or greater than 1.

19. An error correction method, comprising:
reading user data encoded with an error correction code from a nonvolatile memory;
performing error correction decoding based on the error correction code on read data of a size; and
rewriting one or more bits of the read data of a size;
wherein the one or more bits comprise M consecutive bits or a plurality of bits at N-bit intervals, M is a natural number equal to or greater than 1, and N is a natural number equal to or greater than 1.
